(19) United States
(12) Patent Application Publication
(10) Pub. No.: US 2025/0069959 A1
(43) Pub. Date: Feb. 27, 2025

(54) ADAPTIVE WAFER BOW MANAGEMENT

(71) Applicant: Applied Materials, Inc., Santa Clara, CA (US)

(72) Inventor: Mayur Govind Kulkarni, Bangalore (IN)

(73) Assignee: Applied Materials, Inc., Santa Clara, CA (US)

(21) Appl. No.: 18/455,505

(22) Filed: Aug. 24, 2023

(51) Int. Cl. H01L 21/66; H01L 21/67; H01L 21/677; H01L 21/683

(52) U.S. Cl. CPC H01L 22/26; H01L 21/67253; H01L 21/67742; H01L 21/6831

(57) ABSTRACT

A sensor can be configured to measure wafer bowing characteristics associated with a bow of a wafer after a first fabrication process is performed on the wafer in a first processing chamber and before a second fabrication process is performed on the wafer in a second processing chamber. A transfer chamber, including the sensor, can be coupled to a first process chamber and a second process chamber. The wafer bowing characteristics can be used by a controller to determine recipe parameters. The recipe parameters can be used by the controller to control environmental conditions in the transfer chamber and/or processing chamber and cause the processing chamber to perform its associated fabrication process using the recipe parameters.

### TECHNICAL FIELD

This disclosure is generally related to techniques for managing wafer bowing during one or more fabrication processes. More specifically, this disclosure describes detecting wafer bow using a sensor and managing environmental controls and recipe parameters to reduce wafer bow.

### BACKGROUND

In the fabrication of modern semiconductor wafers (and other wafers), fabrication processes can cause bowing in the wafer. Bowing in the wafer can be caused by a variety of factors including the scale (in microns or smaller) of layers and other parts of wafers as they are fabricated. Reducing wafer bowing across fabrication processes can increase the yields for fabrication processes and ensure uniformity and predictability in end products such as semiconductor devices.

### SUMMARY

In some embodiments, a system may include a first processing chamber configured to perform a first fabrication process on a wafer; a second processing chamber configured to perform a second fabrication process on the wafer; a transfer chamber coupled to the first processing chamber and the second processing chamber, wherein the transfer chamber comprises a sensor configured to measure wafer bowing characteristics associated with a bow of the wafer after the first fabrication process is performed on the wafer and before the second fabrication process is performed on the wafer; a controller configured to perform operations including: determining recipe parameters to reduce the bow of the wafer based at least in part on the wafer bowing characteristics; and controlling environmental conditions in the transfer chamber and/or causing the second processing chamber to perform the second fabrication process using the recipe parameters.

In some embodiments, a method to reduce the bow of a wafer may include receiving, from a sensor coupled to a transfer chamber, wafer bowing characteristics associated with a bow of the wafer, the wafer bowing characteristics measured by the sensor, the transfer chamber coupled to a first processing chamber and a second processing chamber, the first processing chamber configured to perform a first fabrication process on the wafer, the second processing chamber configured to perform a second fabrication process on the wafer; determining recipe parameters for reducing the bow of the wafer based at least in part on the wafer bowing characteristics; and causing the second processing chamber to perform the second fabrication process using the recipe parameters.

In some embodiments, one or more non-transitory computer-readable media may include instructions that, when executed by one or more processors, cause the one or more processors to perform operations including: receiving, from a sensor coupled to a transfer chamber, wafer bowing characteristics associated with a bow of the wafer, the wafer bowing characteristics measured by the sensor, the transfer chamber coupled to a first processing chamber and a second processing chamber, the first processing chamber configured to perform a first fabrication process on the wafer, the second processing chamber configured to perform a second fabrication process on the wafer; determining recipe parameters for reducing the bow of the wafer based at least in part on the wafer bowing characteristics; and controlling environmental conditions in the transfer chamber using the recipe parameters.

In any embodiments, any and all of the following features may be implemented in any combination and without limitation. The system may include the second processing chamber including a pedestal, the pedestal including an electrostatic chuck and one or more heating zones. The system may include the pedestal including pins. The system may include causing the second processing chamber to perform the second fabrication process includes causing wafer to soak in the second processing chamber on the pins for a time length based at least in part on the recipe parameters. The system may include causing the second processing chamber to perform the second fabrication process includes causing the second processing chamber to heat to a temperature based at least in part on the recipe parameters. The system may include the one or more heating zones including at least one inner zone and at least one outer zone. The system may include causing the second processing chamber to perform the second fabrication process includes causing the at least one inner heating zone and the at least one outer heating zone to heat to different temperatures to reduce the bow of the wafer, the different temperatures being based at least in part on the recipe parameters. The system may include causing the second processing chamber to perform the second fabrication process by including setting a chucking voltage of the electrostatic chuck based at least in part on the recipe parameters. The system may include causing the second processing chamber to perform the second fabrication process by including adjusting the chucking voltage of the electrostatic chuck based at least in part on an indication of film thickness deposited by the second fabrication process in the second processing chamber. The system may include causing the second processing chamber to perform the second fabrication process includes setting a radio-frequency power applied to the second processing chamber based at least in part on the recipe parameters. The system may include determining recipe parameters for reducing the bow of the wafer being further based at least in part on throughput requirements for the system. The system may include the sensor including a laser, the sensor configured to detect angle of reflection and phase shift. The method/operations may include the wafer bowing characteristics being measured by the sensor as the wafer moves through the transfer chamber between the first processing chamber configured to perform the first fabrication process and the second processing chamber configured to perform the second fabrication process. The method/operations may include wafer bowing characteristics including a type of bowing comprising convex, concave, and combination (e.g., with respect to a notch in the wafer). The method/operations may include the wafer bowing characteristics including displacement of one or more points of the wafer in comparison to a plane or the sensor. The method/operations may include the one or more points being distributed along a line or wide strip across a diameter of the wafer. The method/operations may include the one or more points being distributed along two intersecting lines across the wafer. The method/operations may include the one or more points being distributed along a circle at a radius from a center of the wafer. The method/operations may include determining recipe parameters for reducing the bow of the wafer being further based at least in part on a thickness of film to be deposited by the second fabrication process in the second processing chamber. The method/operations may include controlling environmental conditions in the transfer chamber by including causing the wafer to soak in the transfer chamber for a time length based at least in part on the recipe parameters. The method/operation may include controlling environmental conditions in the transfer chamber by including causing the transfer chamber to heat to a temperature based at least in part on the recipe parameters.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a top plan view of a substrate processing tool or processing system of deposition, etching, baking, and curing chambers, according to some embodiments.

FIG. 2 illustrates a cross-sectional view of an example system for managing wafer bowing, according to some embodiments.

FIG. 3A illustrates a displacement sensor positioned to measure a displacement of the wafer, according to some embodiments.

FIG. 3B illustrates a displacement sensor positioned to measure a displacement of the wafer, according to some embodiments.

FIG. 3C illustrates a plurality of displacement sensors, according to some embodiments.

FIG. 3D illustrates a plurality of displacement sensors positioned at different rotational angles, according to some embodiments.

FIG. 4A illustrates a baseline wafer that may be measured by a displacement sensor, according to some embodiments.

FIG. 4B illustrates a convex wafer, according to some embodiments.

FIG. 4C illustrates a concave wafer, according to some embodiments.

FIG. 5 illustrates a three-dimensional graph of displacement data, according to some embodiments.

FIG. 6 illustrates a graph of displacement data for warped wafers, according to some embodiments.

FIG. 7 illustrates a cross-sectional view of a processing chamber 100, according to some embodiments. The figure is overall ok, but there is a description issue.

FIGS. 8A-8B illustrate a pedestal with a plurality of heating elements arranged in different heating zones, according to some embodiments.

FIG. 9 illustrates a flowchart of a method for using a sensor to determine recipe parameters and/or environmental conditions for performing the fabrication process.

FIG. 10 illustrates an exemplary computer system, in which various embodiments may be implemented.

### DETAILED DESCRIPTION

As the critical dimension or feature sizes of wafers (for example, semiconductor, ceramic, and other types of wafers) have gotten smaller to decrease power consumption and improve other performance characteristics, wafer fabrication has become increasingly complex. Layers are getting thinner and each layer is being more carefully crafted to increase the performance of the overall wafer. The precise fabrication has led to some wafers start to bow during the fabrication process such that the wafer may deform and no longer lie flat. Instead, parts of the wafer, including the edges, may appear to flex upward or downward. However, each wafer can deform in different ways due to minute and subtle changes in environmental and other conditions during the wafer fabrication process. In order to manage and reduce wafer bowing, management of wafer bowing techniques need to be adaptive to variations in deformation. This disclosure describes techniques for the adaptive management of wafer bowing.

A sensor can be used to measure wafer bowing characteristics. The sensor can be located in or coupled to a transfer chamber. The transfer chamber can be between or coupled to both a first process chamber and a second process chamber. Wafer bowing characteristics can include the overall type or shape of the bow (for example, concave, convex, combination, etc.) and the displacement of parts of the bow as detected by the sensor. The wafer bowing characteristics can be used by a controller (which can include one or more processors) to determine recipe parameters. Recipe parameters can include temperature of the transfer chamber, soak time in the transfer chamber, temperature of the process chamber, soak time in the process chamber (for example, on pins of a pedestal), radio frequency power and distribution in the process chamber, chucking voltage of the pedestal, and the distribution of heat/power along different heating zones in the pedestal. The recipe parameters can be used by the controller to control environmental conditions in the transfer chamber and/or processing chamber and cause the processing chamber to perform its associated fabrication process using the recipe parameters.

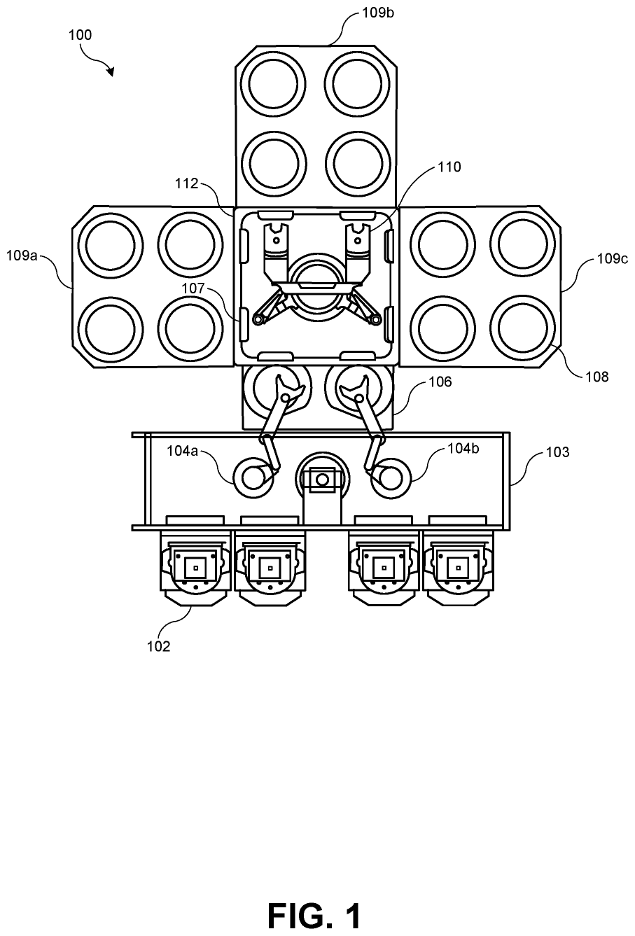

FIG. 1 illustrates a top plan view of a substrate processing tool or processing system 100 of deposition, etching, baking, and curing chambers, according to some embodiments. A set of front-opening unified pods 102 may supply substrates of a variety of sizes that are received within a factory interface 103 by robotic arms 104a and 104b and placed into a load lock or low pressure holding area 106 before being delivered to one of the substrate processing regions 108, positioned in chamber systems or quad sections 109a-c, which may each be a substrate processing system having a transfer region fluidly coupled with a plurality of processing regions 108. Although a quad system is illustrated, it is to be understood that platforms incorporating standalone chambers, twin chambers, and other multiple chamber systems may also be used. A second robotic arm 110 housed in a transfer chamber 112 may be used to transport the substrate wafers from the holding area 106 to the quad sections 109 and back, and second robotic arm 110 may be housed in a transfer chamber with which each of the quad sections or processing systems may be connected. Each substrate processing region 108 can be outfitted to perform a number of substrate processing operations including any number of deposition processes including cyclical layer deposition, atomic layer deposition, chemical vapor deposition, physical vapor deposition, as well as etch, pre-clean, anneal, plasma processing, degas, orientation, and other substrate processes. These chambers may be arranged as twin chambers and/or single chambers in any combination as the specific physical arrangement of chambers in FIG. 1 is provided only by way of example.

Each quad section 109 may include a transfer region that may receive substrates from, and deliver substrates to, second robotic arm 110. The transfer region of the chamber system may be aligned with the transfer chamber having the second robotic arm 110. In some embodiments the transfer region may be laterally accessible to the robot. In subsequent operations, components of the transfer sections may vertically translate the substrates into the overlying processing regions 108. Similarly, the transfer regions may also be operable to rotate substrates between positions within each transfer region. The substrate processing regions 108 may include any number of system components for depositing, annealing, curing and/or etching a material film on the substrate or wafer. In one configuration, two sets of the processing regions, such as the processing regions in quad section 109a and 109b, may be used to deposit material on the substrate, and the third set of processing chambers, such as the processing chambers or regions in quad section 109c, may be used to cure, anneal, or treat the deposited films. In another configuration, all three sets of chambers, such as all twelve chambers illustrated, may be configured to both deposit and/or cure a film on the substrate.

The second robotic arm 110 may include two arms for delivering and/or retrieving multiple substrates simultaneously. For example, each quad section 109 may include two accesses 107 along a surface of a housing of the transfer region, which may be laterally aligned with the second robotic arm. The accesses may be defined along a surface adjacent the transfer chamber 112. In some embodiments, such as illustrated, the first access may be aligned with a first substrate support of the plurality of substrate supports of a quad section. Additionally, the second access may be aligned with a second substrate support of the plurality of substrate supports of the quad section. The first substrate support may be adjacent to the second substrate support, and the two substrate supports may define a first row of substrate supports in some embodiments. As shown in the illustrated configuration, a second row of substrate supports may be positioned behind the first row of substrate supports laterally outward from the transfer chamber 112. The two arms of the second robotic arm 110 may be spaced to allow the two arms to simultaneously enter a quad section or chamber system to deliver or retrieve one or two substrates to substrate supports within the transfer region.

Any one or more of the transfer regions described may be incorporated with additional chambers separated from the fabrication system shown in different embodiments. It will be appreciated that additional configurations of deposition, etching, annealing, and curing chambers for material films are contemplated by processing system 100. Additionally, any number of other processing systems may be utilized with the present technology, which may incorporate transfer systems for performing any of the specific operations, such as the substrate movement. In some embodiments, processing systems that may provide access to multiple processing chamber regions while maintaining a vacuum environment in various sections, such as the noted holding and transfer areas, may allow operations to be performed in multiple chambers while maintaining a particular vacuum environment between discrete processes.

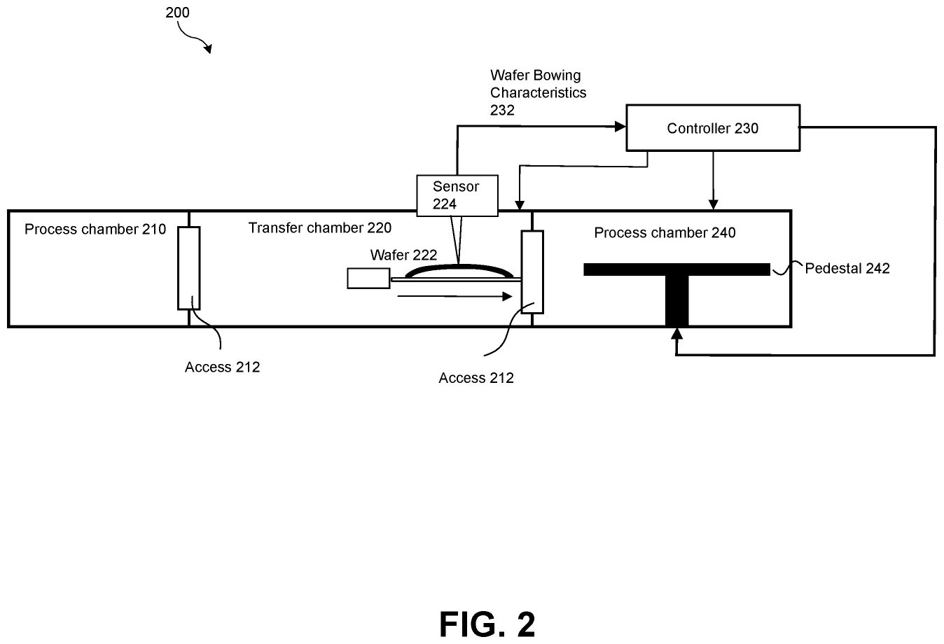

FIG. 2 illustrates a simplified system diagram 200 of a wafer fabrication system for using a sensor 224 to measure wafer bowing characteristics 232 for determining recipe parameters, controlling environmental conditions, and performing fabrication processes, according to some implementations. The sensor 224 can be located in the transfer chamber 220 and can measure wafer bowing characteristics 232 as the wafer 222 is located in or moves around the transfer chamber 220. The wafer 222 can be moving from a first process chamber 210 after a first fabrication process was performed in the first process chamber 210 on the wafer 222. The wafer 222 can be moving to a second process chamber 240 which is configured to perform a second fabrication process on the wafer 222. The wafer 222 can move between the chambers via accesses 212. A process chamber can also be referred to as a processing chamber.

While the wafer 222 is in the transfer chamber 220, the sensor 224 can measure wafer bowing characteristics 232. The transfer chamber 112 of FIG. 1 is an example transfer chamber. The sensor 224 can be a displacement sensor. For example, the sensor 224 can be a laser, an acoustic sensor, an optical sensor (IR, UV, laser) and/or any other type of displacement sensor. The wafer bowing characteristics 232 that can be measured by the sensor 224 may include displacement values of a surface of the wafer 222 in relation to a plane. The plane could relate to a tray or vessel or robot blade that is holding the wafer 222 while the wafer 222 is in the transfer chamber. The wafer bowing characteristics 232 can also include information regarding the type of the wafer bow of the wafer 222. For example, the wafer 222 could have a bow that is convex, concave, or a combination of the two. In some implementations, there can be more than one sensor 224 in the transfer chamber 220. A bow of a wafer can cause a point to measure between nanometers to centimeters away from a base plane. For example, a point in a bow of the wafer can be measured to be 200 microns away from a base plane.

The wafer bowing characteristics 232 can be sent to the controller 230. In some implementations, the controller 230 can control the sensor 224 to obtain measurements. The controller 230 can determine recipe parameters to adaptively manage the bow of the wafer 222 based on the wafer bowing characteristics 232. The recipe parameters can include a temperature of the transfer chamber 220, a soak time in the transfer chamber 220, a temperature of the process chamber 240, a soak time in the process chamber 240 (for example, on pins of a pedestal 242), a radio frequency power and/or a radio frequency power distribution in the process chamber 240, a chucking voltage of the pedestal 242, the distribution of heat/power along different heating zones in the pedestal 242, and other recipe parameters. The recipe parameters can be used by the controller 230 to control environmental conditions in the transfer chamber 220 and/or the processing chamber 240 and cause the processing chamber 240 to perform its associated fabrication process using the recipe parameters. The recipe parameters can also be used by the controller 230 to control any process, system, or parts for moving the wafer 222 from chamber to chamber (for example, the second robotic arm 110 of FIG. 1) or within a chamber. The controller 230 can also take into account other parameters in determining the proper mix of recipe parameters. For example, the required throughput for the overall system and/or specifically the transfer chamber 220 may limit the soak time in the process chamber 240 and/or the soak time in the transfer chamber 220. Similarly, adjusting the temperature of the transfer chamber 220 and the process chamber 240 may take significant time and/or energy. the temperature of the process chamber 240 may also be subject to process constraints for performing a semiconductor process, such as an allowable temperature range for performing a deposition process. The controller 230 is able to adaptively react to these constraints to appropriately balance one or more recipe parameters in reducing the wafer bow of the wafer 222.

The controller 230 can control recipe parameters and environmental conditions associated with the transfer chamber 220. For example, the controller 230 can control how long the wafer stays in the transfer chamber 220 (i.e., how long the wafer soaks in the transfer chamber 220) and the temperature in the transfer chamber 220. To control how long the wafer stays in the transfer chamber 220, the controller 230 can communicate with the transfer chamber 220 and/or the mechanism that moves the wafer 222 around (for example, the second robotic arm 110 of FIG. 1) to cause the wafer 222 to stay in the transfer chamber 220. For example, the controller 230 can control when the accesses 212 open.

The controller 230 can also control the temperature in the in the transfer chamber 220, including while the wafer is soaking in the transfer chamber 220. For example, the controller can cause a heater coupled to the transfer chamber 220 to set a temperature in the transfer chamber 220. Additionally, the controller 230 can the control both the temperature and duration of time the wafer is in the transfer chamber 220 such that wafer soaking in the transfer chamber 220 can have one or more stages of variable duration at one or more temperatures. For example, wafer may soak at a higher temperature for a first stage after entering the transfer chamber 220 and then at a lower temperature for a second stage after the first time period has elapsed. Example temperatures that a controller may set in the transfer chamber include room temperature to 300 Celsius. A controller can also set the temperature in a transfer chamber to be colder than room temperature or higher than 300 Celsius.

Process chambers 210, 240 are configured to perform fabrication processes on wafer 222. Quad section 109 of FIG. 1 is an example process chamber. Process chamber 240 can have a pedestal 242. When the wafer 222 is transported into the process chamber 240 (for example, from the transfer chamber 220), the wafer 222 can be placed onto the pedestal 242. The pedestal 242 can have pins extending upward whereon the wafer can be placed such that the wafer 222 is not resting flat on the pedestal 242. The pins are retractable such that the wafer 222 can be placed on the pedestal 242 when the pins are retracted.

The pedestal 242 can be configured with an electrostatic chuck capability which can be used to reduce the bow of the wafer 222. The electrostatic chuck capability can create a force that pulls the wafer 222 against the pedestal 242 to hold the wafer 222 in place during the process and to reduce the bow of the wafer 222 during the proces. Adjusting the voltage of the electrostatic chuck in the pedestal 242 adjusts the power of the force pulling the wafer 222 against the pedestal 242. Too little voltage may insufficiently reduce the bow of the wafer 222, while too much voltage may overly stress or damage the wafer. As described herein, the controller 230 can identify a proper voltage to apply to the electrostatic chuck of the pedestal based on the measured displacement data.

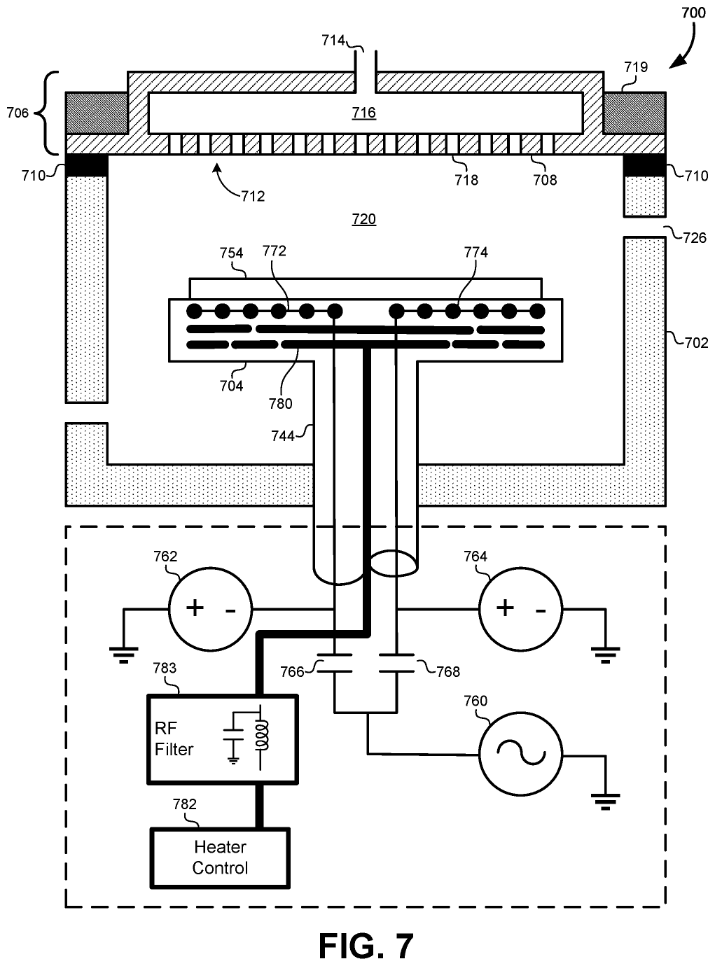

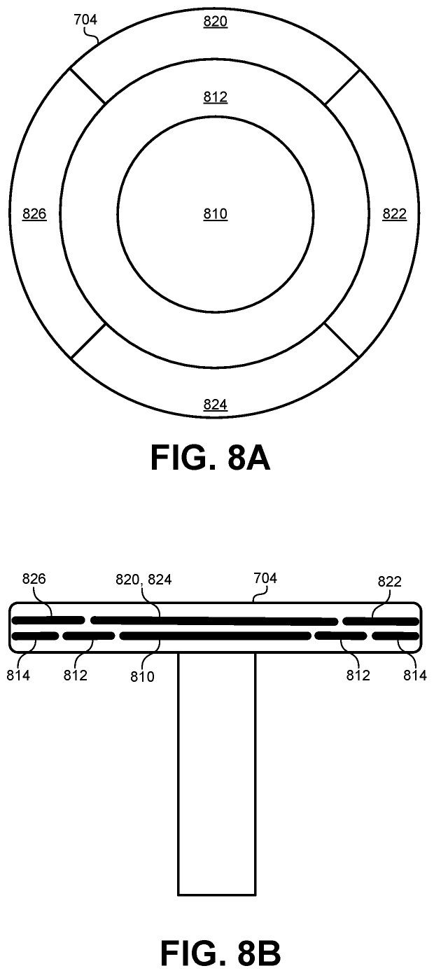

The pedestal 242 also includes a heater that can apply heat to the wafer 222. The heater can include one or more zones which allow for particularized and precise application of heat to the wafer 222. As described herein, the controller 230 can identify the proper zones of the heater to use and at what intensity, power, and/or heat the zones should be used. The controller 230 can also control the distribution, intensity, and/or power of radio frequency (RF) power applied in the process chamber 240 and/or on the pedestal 242. The pedestal 242 is further described herein, for example with relation to FIGS. 7 and 8A-8B.

A number of technical problems exist for managing the bow of a wafer 222. As chip integration has become more complex and required more transistors in an area of a wafer, wafer fabrication has had to include more 3D structures. In creating wafers with 3D structures, different layers are being deposited, modified, etched, and the like under different circumstances that range in terms of heat, pressure, and other conditions. As such, each layer in a wafer can be deposited under different conditions which ends up forming bows in wafers as processes are applied and layers are added and/or removed. Furthermore, although each layer and process a wafer goes through is meant to be precisely duplicated across many wafers, there are still differences that occur between each wafer. As such, management of wafer bow during the fabrication process may benefit from an adaptive approach that can adapt to individual wafers and the variety of processes used during the fabrication of a wafer. Additionally, there can be time and energy constraints to be managed during the fabrication of a wafer. If a particular fabrication process in a particular fabrication processing chamber is a bottleneck, then a controller can determine not to increase the time that a wafer is in that particular chamber (for example, to soak the wafer at a specific temperature for a time period).

Using a sensor to measure wafer bowing characteristics and a controller to determine recipe parameters based on the wafer bowing characteristics can adjust to the individual wafers and adjust based on time, power, temperature ranges, and other constraints and factors. Having an adaptive control method for managing the bow of a wafer can increase yields of a particular system for the fabrication of wafers.

The controller 230 may be implemented by any computer system. For example, the controller 230 may include one or more processors that execute instructions. Instructions may be stored on one or more computer-readable media as a computer program. The controller 230 may be distributed such that multiple computer systems may collectively form the controller 230. For example, a processor coupled to the pedestal 242 may execute a portion of the instructions to control one or more heating zones, while a separate processor that is coupled to the transfer chamber 212 may execute another portion of the instructions. Alternatively, the controller 324 may be implemented using a server, a workstation, or other centralized computer system that communicates with the sensor 224, transfer chamber 220, process chamber 240, pedestal 242, and/or other elements of the system.

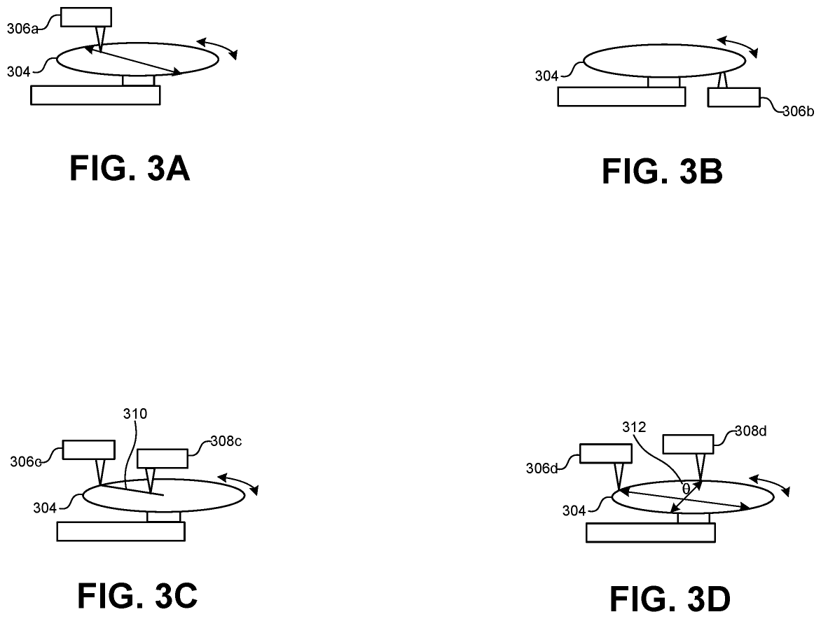

FIG. 3A illustrates a displacement sensor 306a positioned over the wafer 304, according to some embodiments. While displacement measurements are being taken, one or both of the displacement sensor 306a and the wafer 304 move laterally (for example, in the x and y planes rather than up and down in the z plane). In some implementations, the wafer 304 moves and the displacement sensor 306a does not move while the displacement sensor 306a takes measurements. In some implementations, the displacement sensor 306a moves as it takes measurements while the wafer 304 does not move. The displacement sensor 306a and/or the wafer 304 can be moved in a circular fashion. For example, the wafer 304 can spin (or be spun). The movement of both the displacement sensor 306a and the wafer 304 can be controlled by the controller (for example, the controller 230 of FIG. 2). In some implementations, the measurements taken by the displacement sensor 306a are along a diameter line of the wafer 304. In some implementations, the measurements taken by the displacement sensor 306a are along a chord between two points on the edge of the wafer 304. The displacement sensor 306a can also take measurements in a circle at a radius around the center of the wafer 304. The displacement sensor 306a can also take any assortment of measurements around the wafer. For example, the displacement sensor 306a could take measurements along two intersecting lines on the wafer. The displacement sensor 306a may be implemented using a spectrometer in some embodiments.

The displacement measurements may be taken periodically. In some implementations, the displacement sensor 306a takes a displacement measurement at a prescribed distance interval between each measurement (for example, after a combination of the displacement sensor 306a and the wafer 304 have moved). In some implementations, the displacement sensor 306a takes a displacement measurement after an interval of time has elapsed.

FIG. 3B illustrates a displacement sensor 306b positioned to measure a displacement of the bottom of the wafer 304, according to some embodiments. Instead of being positioned above the wafer 304 as illustrated in FIG. 3A, the displacement sensor 306b may be placed underneath the wafer 304. This position of the displacement sensor 306b may provide specific technical advantages. Specifically, when a robotic arm is used to move the wafer 304 to/from the system, the displacement sensor 306b positioned below the wafer 304 will typically not interfere with the movement of the wafer 304 by the robotic arm as it lifts the wafer 304. Another technical advantage provided by this arrangement involves the effect of light-emitting displacement sensors on semiconductor devices. Typically, devices on the wafer may be laid out and exposed on the top side of the wafer 304. By placing the displacement sensor 306b underneath the wafer 304, the system can avoid shining lasers or other high-intensity light sources onto these semiconductor devices. This may be advantageous when these semiconductor devices are particularly sensitive to high-intensity light.

FIG. 3C illustrates a plurality of displacement sensors 306c, 308c, according to some embodiments. In this example, a plurality of displacement sensors 306c, 308c may be positioned on a radial line 310 extending out from the center of the wafer 304. This allows the system to measure displacement data at multiple points at each angle of rotation. Although the example of FIG. 3C illustrates two displacement sensors 306c, 308c, this number of displacement sensors is provided only by way of example and is not meant to be limiting. Other embodiments may include more than two displacement sensors. With multiple displacement sensors measuring displacement data along the radial line 310, the system can generate a displacement map of multiple locations on the wafer 304 to create a displacement mapping of the entire surface of the wafer 304 rather than just one or more lines of the wafer. Prior to this disclosure, a metrology station that performs a laser scan of the entire surface of the wafer 304 was required in order to generate an accurate view of many different aspects of the wafer 304. However, the metrology station is expensive and time-consuming to operate. Providing a plurality of displacement sensors 306c, 308 as depicted in FIG. 3C may replace at least a portion of the operations performed by the metrology station with a low-cost, high-speed process to provide a surface mapping of displacement data for the wafer 304, and these operations may be performed without breaking a vacuum environment around the wafer.

FIG. 3D illustrates a plurality of displacement sensors 306d, 308d positioned at different rotational angles, according to some embodiments. Instead of placing the displacement sensors 306d, 308d along a same radial line at different radial distances, some embodiments may position the displacement sensors 306d, 308d at a known angle of rotation 312. Having multiple lines of measurements may provide a better picture of the bowing of a wafer. Note that more than two displacement sensors may also be used without limitation.

Combinations of the different displacement sensor numbers and/or locations illustrated in FIGS. 3A-3B may be used in any combination and without limitation. For example, some embodiments may include multiple displacement sensors at different angles of rotation and/or different radial distances on a top side of the wafer, while optionally including additional displacement sensors at different angles of rotation and/or different radial distances on a bottom side of the wafer. Some embodiments may also use different sensor types or settings when multiple displacement sensors are used. For example some embodiments may use multiple laser displacement sensors, each operating with a different light frequency. Different frequencies may reflect differently off of the wafer, so using different light frequencies for different sensors may improve the accuracy of the overall displacement data measurement. Additionally, some embodiments may use different sensor types when multiple displacement sensors are used. For example, a laser displacement sensor may be used in one location while an ultrasonic displacement sensor may be used in another location.

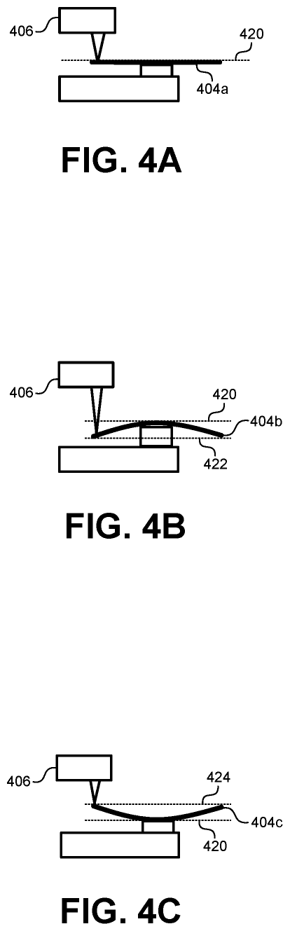

FIG. 4A illustrates a baseline wafer 404a that may be measured by a displacement sensor 406, according to some embodiments. The baseline wafer 404a may be an ideal flat wafer in the z-plane. In other words, the baseline wafer 404a may generate a displacement data that shows a constant baseline displacement 420 that aligns with the surface of the wafer 404a. The constant baseline displacement 420 may also be referred to as a plane or a ground plane. Alternatively, the constant baseline displacement 420 may be referred to as the displacement from a plane or a ground plane. The displacement data received from the baseline wafer 404a may be used to characterize the relative displacement of other subsequent wafers that are measured by the system. The baseline wafer 404 may be measured as part of a calibration or initialization process for the system. The displacement data from subsequent measurements of subsequent wafers may be subtracted from the displacement data from the baseline wafer. Although not shown explicitly in FIG. 4A, embodiments that include multiple displacement sensors may store baseline displacement data for each sensor. Displacement data measured from subsequent wafers may be subtracted from the baseline displacement data for each corresponding displacement sensor.

FIG. 4B illustrates a convex wafer 404b, according to some embodiments. A convex profile indicates that the wafer 404b has bowed or warped downwards at the edges of the wafer 404b relative to the center of the wafer. A displacement 422 may be larger than the baseline displacement 420, resulting in negative values for the displacement 422 when subtracted from the baseline displacement 420. Of note, convex wafer 404b does not necessarily have to be symmetrically bowed or warped around the center of the convex wafer 404b. Some portions of convex wafer 404b may be more or less warped than other portions, which the sensor 406 can detect and measure. Similarly, FIG. 4C illustrates a concave wafer 404c, according to some embodiments. A concave profile indicates that the wafer 404c has bowed or warped upwards at the edge of the wafer 404c relative to the center of the wafer. A displacement 424 may be smaller than the baseline displacement 420, resulting in positive values for the displacement 424 when subtracted from the baseline displacement 420. Of note, concave wafer 404c does not necessarily have to be symmetrically bowed or warped around the center of the concave wafer 404c. Some portions of concave wafer 404c may be more or less warped than other portions, which the sensor 406 can detect and measure. In some situations, a wafer can bow or warp in a way where portions are convex or concave. For example, portions of the outer edge of the wafer can bow upwards while other portions of the outer edge of the wafer can bow downwards. Wafers that have portions of both concave and convex bows can be considered and referred to as having combination bowing and/or “potato chip” bowing.

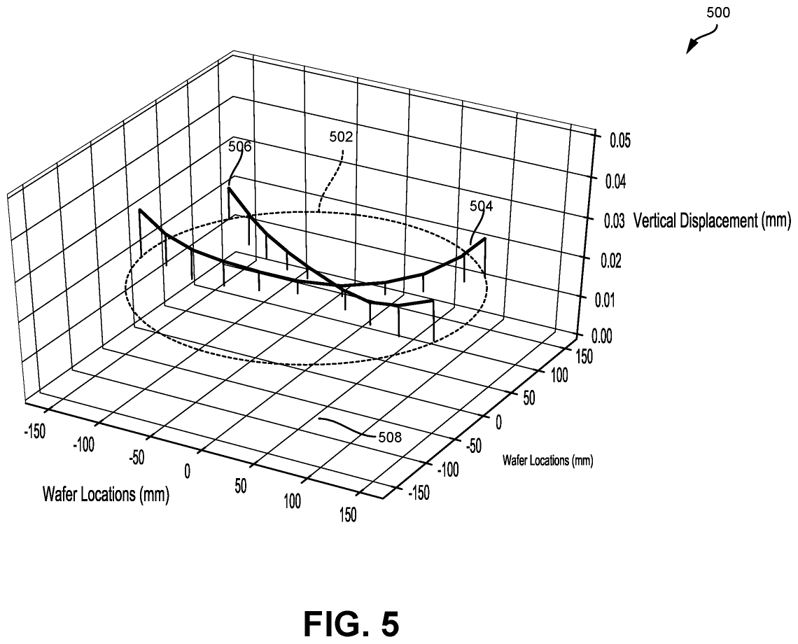

FIG. 5 illustrates a three-dimensional (3D) graph 500 of the displacement data, according to some embodiments. The graph 500 includes distance measurements relative to a default or baseline displacement of the wafer. Locations on the wafer may be mapped into Cartesian coordinates on a millimeter scale. These coordinates may be assigned based on a predetermined alignment. For example, a notch along the edge for alignment may be used for alignment. For example, the notch location may be assigned a coordinate position of (0, 150) in the (x, y) plane of the graph 500. Thus, once the alignment position in the displacement data have been captured, some embodiments may rotate the displacement data to conform with the coordinate locations based on the notch location.

In this example, the displacement data is stored as a vertical distance relative to a baseline location. For example, a ring 502 may represent a baseline location of the wafer when no bow or warping is present. Series of data points 504, 506 can represent displacements and/or measurements taken by displacement sensors. In some implementations, the same sensor can measure both series of data points 504, 506. In some implementations, different sensors can each measure a series of data points. Some data points representing distances measured above the baseline location may be represented as positive displacements. These data points may correspond to locations on the wafer that have bowed or warped upwards relative to a center of the wafer. Some data points representing distances measured below the baseline location may be represented as negative displacements. These data points may correspond to locations on the wafer that have bowed or warped downwards relative to a center of the wafer.

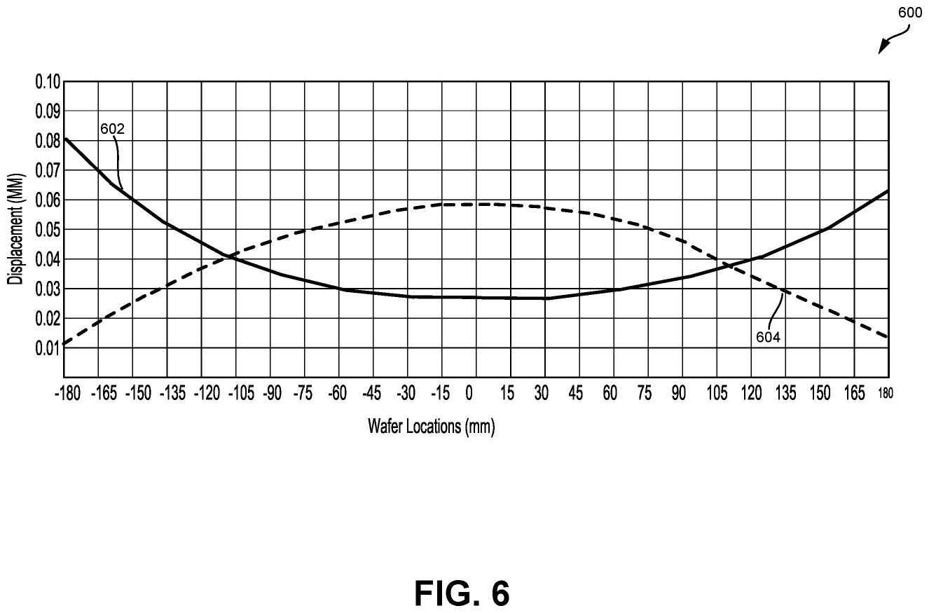

FIG. 6 illustrates a graph 600 of displacement data for warped wafers, according to some embodiments. Instead of being mapped to 2D coordinates on a 3D axis, the displacement data may be mapped to a 2D axis, where the x-axis indicates a distance from the center of the wafer, and the y-axis indicates a displacement relative to a baseline. The displacement data can also be mapped to an angle of rotation. The mapping to the angle of rotation may also be based on the alignment data to determine an origin for the rotation. Displacement data 602 corresponds to a wafer that may include a concave when viewed from above. Displacement data 604 corresponds to a wafer with a convex when viewed from above. Some wafers can have multiple concave and convex portions. Such a wafer may be characterized as having a combination bow. Displacement data for wafers can also include convexes and concaves that are not centered at the center of the wafer. In some implementations, a sensor may not measure along a diameter of the wafer, but rather along a straight line between two points on the edge of the wafer. Because wafers are roughly circular when viewed from above, the straight line between two points on the edge of the wafer can be referred to using the geometrical term of a chord. As such, a sensor can measure along a chord of a wafer. Graph 600 illustrates how displacement data for any type of warped or bow condition in wafer may be characterized by the system described herein. In some implementations, the sensor can take a set number of measurements. For example, the sensor can take 10-15 measurements. In some implementations, the sensor can take as many measurements as necessary based on the time interval or distance interval between measurements.

The mapping to the 2D coordinates of FIG. 5, or the mapping to distance from the center of a wafer in FIG. 6 can be referred to as wafer bowing characteristics (for example, the wafer bowing characteristics 232 of FIG. 2). For example, the 2D coordinates of FIG. 5 may be used to identify 2D regions in the wafer that are bowed and need to be managed. Many wafer bowing management techniques are described herein. Other methods for managing the bowing can include the identified regions being polished more heavily, cleaned more heavily, or being subject to differential pressures during a polishing process. For example, these differential pressures may include lower pressures in some areas and higher pressure in other areas to compensate for irregularities in the wafer as represented in the displacement data. Contiguous areas of displacement on a wafer may be grouped together into a region and mapped to a particular pressurized chamber. These regions on the wafer may be identified in the mapped data described above.

FIG. 7 illustrates a cross-sectional view of a wafer-processing chamber 700, according to some embodiments. As shown, the processing chamber 700 may be an etch chamber suitable for etching a substrate 754 (for example, the wafer 222 of FIG. 2) or for performing other wafer manufacturing operations. The processing chamber 700 is an example of a process chamber 240 of FIG. 2. Examples of processing chambers that may be adapted to benefit from the embodiments describe herein may include the Producer® Etch Processing Chamber, and the Precision™ Processing Chamber, commercially available from Applied Materials, Inc., located in Santa Clara, California. It is contemplated that other processing chambers, including those from other manufacturers, may be adapted to benefit from these embodiments.

The processing chamber 700 may be used for fabrication processes related to fabricating wafers, such as various plasma processes. For example, the processing chamber 700 may be used to perform dry etching with one or more etching agents. The processing chamber may be used for ignition of plasma from a precursor CₓF_{y} (where x and y represent values for known compounds), O₂, NF₃, or combinations thereof. In another example, the processing chamber 700 may be used for a plasma-enhanced chemical vapor deposition (PECVD) process with one or more precursors. The processing chamber 700 can also be used for other fabrication processes such as deposition of films, doping, and other fabrication processes used in wafer fabrication.

The processing chamber 700 may include a chamber body 702, a lid assembly 706, and a pedestal 704. The lid assembly 706 is positioned at an upper end of the chamber body 702. The pedestal 704 may be disposed inside the chamber body 702, and the lid assembly 706 may be coupled to the chamber body 702 and enclose the pedestal 704 in a processing volume 720. The chamber body 702 may include a transfer port 726, which may include a slit valve, formed in a sidewall of the chamber body 702. The transfer port 726 (for example, access 212 of FIG. 2) such as the access may be selectively opened and closed to allow access to an interior of the processing volume 720 by a wafer handling robot (not shown) for wafer transfer.

An electrode 708 may be provided as a portion of the lid assembly 706. The electrode 708 may also function as a gas distributor plate 712 having a plurality of openings 718 for admitting process gas into the processing volume 720. The process gases may be supplied to the processing chamber 700 via a conduit 714, and the process gases may enter a gas mixing region 716 prior to flowing through the openings 718. The electrode 708 may be coupled to a source of electric power, such as an RF generator, DC power, pulsed DC power, pulsed RF, and/or the like. An isolator 710 may contact the electrode 708 and separate the electrode 708 electrically and thermally from the chamber body 702. The isolator 710 may be constructed using a dielectric material such aluminum oxide, aluminum nitride, and/or other ceramics, metal oxides, plastics (such as PTFE), and so forth. A heater 719 may be coupled to the gas distributor plate 712. The heater 719 may also be coupled to an AC power source.

A controller (for example, the controller 230 of FIG. 2) can control environmental conditions associated with the processing chamber 700 and perform a fabrication process associated with the processing chamber 700 based on the recipe parameters. For example, the controller can control the wafer soak time in the processing chamber 700 and the temperature in the processing chamber 700. To control how long the wafer stays in the processing chamber 700, the controller can communicate with the processing chamber 700 and/or the mechanism that moves the wafer around (for example, the second robotic arm 110 of FIG. 1) to cause the wafer to stay in the processing chamber 700. For example, the controller can control when the transfer port 726 to the processing chamber 700 opens. The controller can also control how the wafer soaks in the processing chamber 700. For example, the controller can cause pins to extend upward from the pedestal 704 such that the wafer does not contact the surface of the pedestal 704. The wafer can also rest on the pedestal 704 itself.

The controller can also control the temperature in the in the processing chamber 700, including while the wafer is soaking in the processing chamber 700. For example, the controller can cause the heater 719, which is coupled to the processing chamber 700, to set a temperature in the processing chamber 700. The controller may also control the temperature separately for an inner and outer zone to compensate for bow in the substrate. Additionally, the controller can the control both the temperature and duration of time the wafer is in the processing chamber 700 such that wafer soaking in the processing chamber 700 can have one or more stages of variable duration at one or more temperatures. For example, wafer may soak at a higher temperature for a first stage after entering the processing chamber 700 and then at a lower temperature for a second stage after the first time period has elapsed. Example temperatures that a controller may set in the processing chamber 700 include room temperature to 300 Celsius. A controller can also set the temperature in a processing chamber to be much colder than room temperature or much higher than 300 Celsius.

The pedestal 704 may be coupled to a lift mechanism through a shaft 744, which extends through a bottom surface of the chamber body 702. The lift mechanism may be flexibly sealed to the chamber body 702 by a bellows that prevents vacuum leakage from around the shaft 744. The lift mechanism may allow the pedestal 704 to be moved vertically within the chamber body 702 between a transfer position and a number of process positions to place the substrate 754 in proximity to the electrode 708.

The pedestal 704 may be formed from a metallic or ceramic material. For example, a metal oxide, nitride, or oxide/nitride mixture may be used such as aluminum, aluminum oxide, aluminum nitride, an aluminum oxide/nitride mixture, and/or other similar materials. In typical implementations, one or more pedestal electrodes may be included in the pedestal 704. For example, a first pedestal electrode 772 and a second pedestal electrode 774 may be provided in the pedestal 704. The first pedestal electrode 772 and the second pedestal electrode 774 may be embedded within the pedestal 704 and/or coupled to a surface of the pedestal 704. The first pedestal electrode 772 and the second pedestal electrode 774 may be a plate, a perforated plate, a mesh, a wire screen, or any other distributed conductive arrangement. Although FIG. 7 illustrates only two pedestal electrodes, other embodiments may use more than two pedestal electrodes having different geometries and/or arrangements in the pedestal 704 as described in detail below.

A controller (for example, the controller 230 of FIG. 2) can control environmental conditions and perform a fabrication process associated with the processing chamber 700 based on the recipe parameters by using RF energy. For example, the controller can be configured to control how one or more pedestal electrodes deliver RF energy to a plasma in the processing volume 720. For example, an RF source 760 may be provided outside of the chamber body 702 to provide RF energy to one or more pedestal electrodes in the pedestal 704. The controller can control the RF source 760. The RF energy may be transferred through the one or more pedestal electrodes to a gas in the processing volume 720 that is deposited through the gas distributor plate 712 (also referred to as a “showerhead”) to generate a plasma. The RF energy can be used to reduce wafer bowing of a wafer that is in the processing chamber 700. In some implementations, the plasma can be maintained above the substrate 754 to deposit a layer of material on the substrate 754. In order to uniformly deposit material on the substrate 754, the energy transferred to the plasma should be maintained uniformly across the surface area of the substrate 754.

The controller (for example, the controller 230 of FIG. 2) can control environmental conditions and perform a fabrication process associated with the processing chamber 700 based on the recipe parameters by using electrostatic chucking. Bipolar chucking can be used with a first pedestal electrode 772 and a second pedestal electrode 774 and controlled by the controller. Bipolar chucking applies a DC voltage difference between the first pedestal electrode 772 and the second pedestal electrode 774. This electrostatic difference serves to hold the substrate 754 to the pedestal 704. Holding a wafer to the pedestal 704 can reduce wafer bowing. The controller is also able to control the first pedestal electrode 772 and/or the second pedestal electrode 774 to implement monopolar chucking where only a single pedestal electrode is used, or where a DC voltage is only applied to a single pedestal electrode. Monopolar chucking can be effective when energy is applied to the plasma to complete the circuit. Bipolar chucking uses two separate electrical paths to each of the first pedestal electrode 772 and the second pedestal electrode 774. In the example of FIG. 7, a first DC voltage source 762 is applied to a first electrical pathway for the first pedestal electrode 772. A second DC voltage source 764 is applied to a second electrical pathway for the second pedestal electrode 774. The controller is able to control both the first DC voltage source 762 and the second DC voltage source 764. In some implementations, the chucking voltage applied can be 300-350 volts. In some implementations, the chucking voltage applied can be up to 950 volts. Lower voltages can be advantageous in order to reduce scratches to the wafer from particles as the wafer is flattened and/or help against the pedestal by the electrostatic chuck. In some implementations, the controller can change the chucking voltage based on the thickness of the film deposited on the wafer. For example, as the thickness of the film deposited on the wafer increases, the controller can increase the chucking voltage. Some embodiments may include one or more capacitors 766, 768 to isolate the DC voltage sources 762, 764 from each other and/or to the voltage source 760. In some embodiments, each of the capacitors 766, 768 may be relatively large, such as 50 nF to block the DC voltage.

In addition to the one or more pedestal electrodes 772, 774, some embodiments may also include one or more heating elements 780 in the pedestal 704. A controller (for example, the controller 230 of FIG. 2) can control recipe parameters and environmental conditions associated with the one or more heating elements 780 in the processing chamber 700. The one or more heating elements 780 may include wires with a relatively low internal resistance that generate heat when an electrical current is run through the one or more heating elements 780. For example, some heating elements may have a resistance of less than 10 ohms, such as 2 ohms. Power may be provided to the one or more heating elements 780 by a heater control 782 which is in turn controlled by the controller. The heater control 782 (in response to control signals from the controller) may provide voltage/current to the one or more heating elements 780 during a processing cycle to heat the pedestal 704. This heat may be transferred to the substrate 754 to bring the substrate 754 into a predetermined temperature range during the process.

In some embodiments, an RF filter 783 may be included between the heater control 782 and the one or more heating elements 780. The RF filter may prevent RF signals from leaking into the AC network. The RF filter 783 may include a plurality of inductor/capacitor combinations for each input and/or output lead to/from the heater control 782. For example, each individual RF filter in the RF filter 783 may include a parallel capacitance (e.g., approximately 50 nF) and a series inductor (e.g., approximately 6 μH) to filter out RF signals on each of these lines. In total, some embodiments may include a total of nine rods or leads from the pedestal 704, including two high-voltage leads for chucking, and seven leads for different heater zones. In the seven-zone configuration described herein, zones 1-3 may share a common return rod, and zones 4-7 may share a common return rod.

A number of technical problems exist for providing controlled temperature profiles to the substrate 754. When using a single heating element, the temperature profile of the substrate 754 may be non-uniform. For example, temperatures may be higher in the center of the substrate 754 than temperatures at the periphery of the substrate 754. In another example, the temperature profile may resemble an “M” shape, with lower temperatures in the center and periphery of the substrate 754 and higher temperatures between the middle of the substrate 754 and the periphery of the substrate 754. Modern substrate processes are beginning to require tighter temperature control, which often may benefit from a uniform temperature profile across the substrate 754. Other processes may benefit from programmable temperature profiles that decrease/increase temperature according to a predetermined temperature profile that can be monitored and adjusted in real time as the process is executed. For example, when reducing wafer bow a non-uniform temperature profile in a wafer may be useful.

To tightly control the temperature profile on the substrate 754, a plurality of heating elements may be used in the pedestal 704. However, introducing a plurality of heating elements also introduces additional technical problems. Because of the low resistance associated with the wires of the heating elements, each additional heating element may increase the current requirements of the heater control 782. This not only increases the current required to power the heating elements, but it also increases the current running through internal circuits of the heater control 782. For example, an RF filter may include an inductor that used in the heater control 782 to prevent an RF signal from the RF source 760 from interfering with the heater control 782. As current through the inductor increases, the heat generated in the inductor may also increase proportionally. This may result in damage to the internal circuitry of the filter and/or may generate excessive heat in the electronics controlling the processing chamber 700.

The embodiments described herein solve these and other technical problems by providing a heater control 782 that can efficiently provide power to multiple different heating elements in the pedestal 704. These embodiments may be configured to provide power for high-power heating elements, as well as low-power heating elements that may be used to fine-tune the temperature profile across the substrate 754. This heater control 782 may share return wires to minimize the number of leads from the pedestal 704. The heater control 782 may also duty cycle the various heating elements in order to maintain an acceptable level of current running through the shared return lead. Some embodiments may also switch the polarity of the heating elements such that the voltage differential across the heating elements does not interfere with the DC bipolar chucking of the substrate 754.

FIGS. 8A-8B illustrate a pedestal 704 with a plurality of heating elements arranged into different heating zones, according to some embodiments. The controller (for example, the controller 230 of FIG. 2) can control recipe parameters and environmental conditions associated with the plurality of heating elements arranged into different heating zones of the pedestal 704. In this example, the plurality of heating elements may include seven separate and distinct heating elements. Note that this arrangement and the number of heating elements is provided only by way of example and is not meant to be limiting. The heater control described herein may be used with any number of heating elements. Furthermore, the heating control may be compatible with different arrangements of heating element types. As described below, the heater control may include leads that are compatible with high-power heating elements and low-power heating elements interchangeably. As described herein, the heater control can receive and/or be controlled by a controller (for example, the controller 230 of FIG. 2).

In this example, the pedestal 704 may include a number of high-powered heating elements that are arranged in concentric circular areas on the pedestal 704. A center or inner heating element 810 may have a disk or circular shape and be centered in the pedestal 704. In some implementations, the inner heating element can have a diameter of 200 mm. In some implementations, the inner heating element can have a smaller or larger diameter depending on the expected size of the wafer. A middle heating element 812 may have a ring shape and may be positioned concentrically around the inner heating element 810. An outer heating element 814 may also have a ring shape and may be positioned concentrically around the middle heating element 812. These heating elements 810, 812, 814 may be configured to receive current from the heater control such that they can generate heat in the kilowatt range. These heating elements 810, 812, 814 may be used to set the primary temperature of the substrate. For example, to heat the substrate to temperatures of around 300° C. to around 800° C., the processing chamber may rely on these heating elements 810, 812, 814 with higher power ranges to provide the primary heat for heating the substrate to this temperature range. In some implementations, the outer zones can have a width of 120-320 mm.

This example may also include a number of low-power heating elements that are arranged around a periphery of the pedestal 704. The periphery of the pedestal 704 may be divided into quadrants, and a heating element may be located and shaped to cover each of the quadrants. For example, heating element 820, heating element 822, heating element 824, and heating element 826 may be arranged around the periphery. These heating elements may be arranged in a ring that may be similar in diameter to the outer heating element 814. In the cross-sectional view of the pedestal 704, these low-power heating elements 820, 822, 824, 826 may be placed on top of the high-power heating elements 810, 812, 814, or vice versa. The low-power heating elements 820, 822, 824, 826 may be used to fine-tune the temperature profile in specific areas of the pedestal 704. Note that the specific geometry and arrangement of the low-power heating elements 820, 822, 824, 826 are provided only by way of example and are not meant to be limiting. The low-power heating elements 820, 822, 824, 826 may use power that is less than 100 W, such as between approximately 10 W and approximately 40 W. Other embodiments may include more or fewer low-power heating elements, which may be located in any of the middle, inner, and/or outer regions of the pedestal 704.

By controlling and operating the different heating elements 810, 812, 814, 820, 822, 824, 826, the controller is able to reduce wafer bowing. The controller can fine-tune the temperature profile in specific areas of the pedestal 704 which in such a way that may be unique to the specific wafer bowing characteristics of the wafer as detected by a sensor (for example, the sensor 224 of FIG. 2).

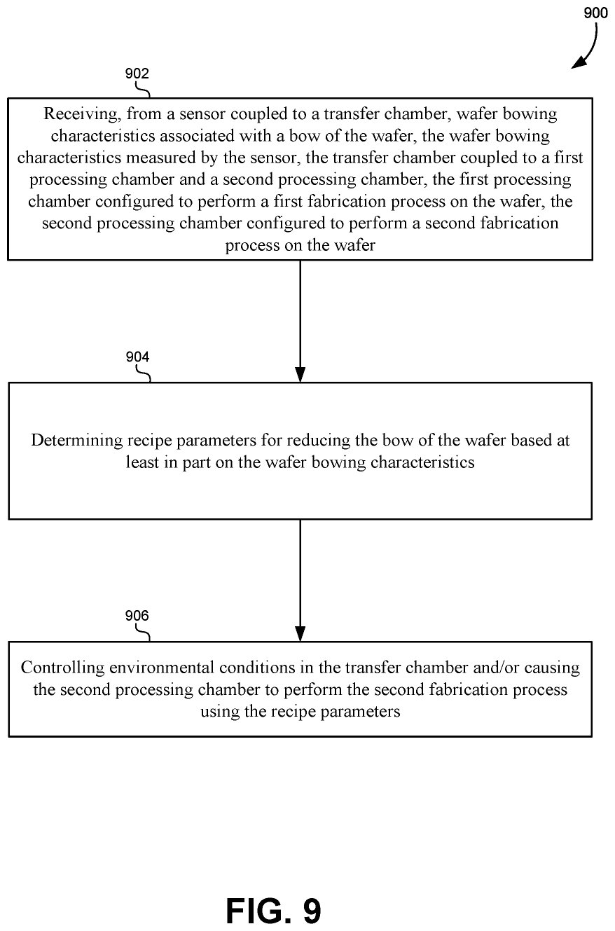

FIG. 9 illustrates a flowchart 900 of a method for using a sensor to determine recipe parameters and/or environmental conditions for performing the fabrication process. This method may be carried out by the controller that generates the signals for controlling the transfer chamber, process chamber, sensor, pedestal, and other elements as illustrated above in FIGS. 2-8. This method may be carried out by a controller having processors that execute instructions to perform these operations.

The method may include receiving, from a sensor, wafer bowing characteristics associated with a bow of the wafer (902). The wafer bowing characteristics may be measured by the sensor as described in FIGS. 2-6. The wafer bowing characteristics may include one or more measurements of a displacement between the surface of the wafer and a ground plane as described herein. The wafer bowing characteristics may also include displacement of one or more points of the wafer in comparison to a plane or the sensor. The wafer bowing characteristics may also include an indication of a type of bowing such as convex, concave, or combination bowing. The one or more points may be distributed along a line across a diameter of the wafer. The may or more points may be distributed along two intersecting lines across the wafer. The one or more points may be distributed along a circle at a radius from a center of the wafer. As described above in FIGS. 3-6, the one or more points may be distributed in many different configurations.

As described above in FIG. 2, the sensor may be coupled to a transfer chamber. The sensor may include a laser and be configured to detect an angle of reflection and a phase shift. The transfer may be coupled to a first processing chamber and a second processing chamber. The first processing chamber may be configured to perform a first fabrication process on the wafer. The second processing chamber may be configured to perform a second fabrication process on the wafer. The wafer bowing characteristics may be measured by the sensor as the wafer moves through the transfer chamber between the first processing chamber and the second processing chamber.

As described above in FIG. 7, the second fabrication chamber may include a pedestal. The pedestal may include an electrostatic chuck and one or more heating zones. The pedestal may include pins. When soaking in the second processing chamber, the wafer can soak while resting on the pins. The one or more heating zones can include at least one inner zone and at least one outer zone.

The method may additionally include determining recipe parameters to reduce the bow of the wafer based at least in part on the wafer bowing characteristics (904). As described in FIG. 2, a controller may determine the recipe parameters after receiving the wafer bowing characteristics from the sensor. The recipe parameters for reducing the bow of the wafer may be based at least in part on throughput requirements for the system fabricating the wafers. The recipe parameters may also be based at least in part on a thickness of film to be deposited by the second fabrication process in the second processing chamber. The recipe parameters may include temperatures, pressures, or other mechanical settings for the second processing chamber. For example, the recipe parameters may be adjusted to reduce the bow of the wafer by adjusting a spacing between the wafer and the shower head in the first or second processing chamber to dynamically adjust deposition rate or uniformity.

The method may additionally include controlling environmental controls in the transfer chamber using the recipe parameters (906). As described in FIGS. 2, 7, 8A, and 8B, a controller can determine environmental controls in the transfer chamber and/or the second processing chamber. The controller may cause the wafer to soak in the transfer chamber for a time length based at least in part on the recipe parameters. The controller may cause the transfer chamber to change its temperature or set its temperature based at least in part on the recipe parameters.

The method may additionally or alternatively include causing the second processing chamber to perform the second fabrication process using the recipe parameters (906). As described in FIGS. 2, 7, 8A, and 8B, a controller may cause the second processing chamber to perform the second fabrication process using the recipe parameters. The controller may cause the wafer to soak in the second processing chamber for a time length based at least in part on the recipe parameters. The wafer may soak on the pins of the pedestal or on the pedestal itself. The controller may cause the second processing chamber to set (or heat) to a temperature based at least in part on the recipe parameters. The controller may cause at least one inner heating zone and at least one outer heating zone to heat to different temperatures to reduce the bow of the wafer, the different temperatures based at least in part on the recipe parameters. The controller may cause any combination of temperatures for the one or more heating zones based at least in part on the recipe parameters. The controller may set a checking voltage for the electrostatic chuck of the pedestal based at least in part on the recipe parameters. The controller may adjust the chucking voltage of the electrostatic chuck based at least in part on the recipe parameters. The controller may adjust the chucking voltage of the electrostatic chuck based on an indication of film thickness to deposited by the second fabrication process in the second processing chamber. For example, as the thickness of the film deposited on the wafer increased, the chucking voltage may need to increase. The controller may set an RF power to be applied to the second processing chamber, the wafer, parts of the wafer, to the pedestal, and elsewhere as described in FIGS. 7, 8A, and 8B based at least in part on the recipe parameters.

Each of the methods described herein may be implemented by a computer system. Each step of these methods may be executed automatically by the computer system, and/or may be provided with inputs/outputs involving a user. For example, a user may provide inputs for each step in a method, and each of these inputs may be in response to a specific output requesting such an input, wherein the output is generated by the computer system. Each input may be received in response to a corresponding requesting output. Furthermore, inputs may be received from a user, from another computer system as a data stream, retrieved from a memory location, retrieved over a network, requested from a web service, and/or the like. Likewise, outputs may be provided to a user, to another computer system as a data stream, saved in a memory location, sent over a network, provided to a web service, and/or the like. In short, each step of the methods described herein may be performed by a computer system, and may involve any number of inputs, outputs, and/or requests to and from the computer system which may or may not involve a user. Those steps not involving a user may be said to be performed automatically by the computer system without human intervention. Therefore, it will be understood in light of this disclosure, that each step of each method described herein may be altered to include an input and output to and from a user, or may be done automatically by a computer system without human intervention where any determinations are made by a processor. Furthermore, some embodiments of each of the methods described herein may be implemented as a set of instructions stored on a tangible, non-transitory storage medium to form a tangible software product.

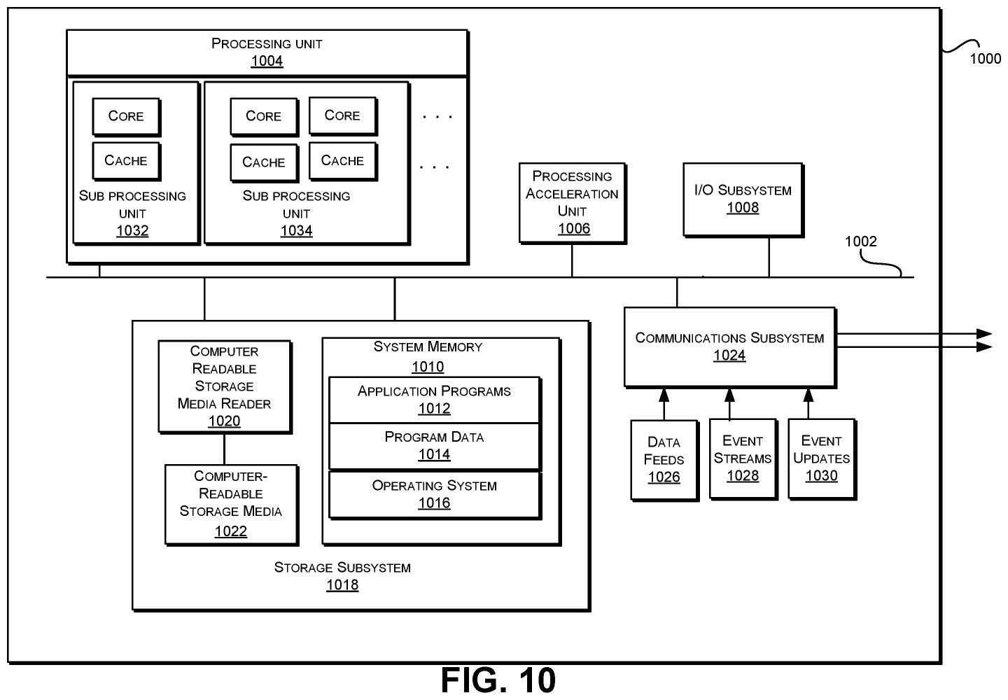

FIG. 10 illustrates an exemplary computer system 1000, in which various embodiments may be implemented. The system 1000 may be used to implement any of the computer systems described above. As shown in the figure, computer system 1000 includes a processing unit 1004 that communicates with a number of peripheral subsystems via a bus subsystem 1002. These peripheral subsystems may include a processing acceleration unit 1006, an I/O subsystem 1008, a storage subsystem 1018 and a communications subsystem 1024. Storage subsystem 1018 includes tangible computer-readable storage media 1022 and a system memory 1010.

Bus subsystem 1002 provides a mechanism for letting the various components and subsystems of computer system 1000 communicate with each other as intended. Although bus subsystem 1002 is shown schematically as a single bus, alternative embodiments of the bus subsystem may utilize multiple buses. Bus subsystem 1002 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 1004, which can be implemented as one or more integrated circuits (e.g., a conventional microprocessor or microcontroller), controls the operation of computer system 1000. One or more processors may be included in processing unit 1004. These processors may include single core or multicore processors. In certain embodiments, processing unit 1004 may be implemented as one or more independent processing units 1032 and/or 1034 with single or multicore processors included in each processing unit. In other embodiments, processing unit 1004 may also be implemented as a quad-core processing unit formed by integrating two dual-core processors into a single chip.

In various embodiments, processing unit 1004 can execute a variety of programs in response to program code and can maintain multiple concurrently executing programs or processes. At any given time, some or all of the program code to be executed can be resident in processor(s) 1004 and/or in storage subsystem 1018. Through suitable programming, processor(s) 1004 can provide various functionalities described above. Computer system 1000 may additionally include a processing acceleration unit 1006, which can include a digital signal processor (DSP), a special-purpose processor, and/or the like.

I/O subsystem 1008 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices.

User interface input devices may also include, without limitation, three dimensional (3D) mice, joysticks or pointing sticks, gamepads and graphic tablets, and audio/visual devices such as speakers, digital cameras, digital camcorders, portable media players, webcams, image scanners, fingerprint scanners, barcode reader 3D scanners, 3D printers, laser rangefinders, and eye gaze tracking devices. Additionally, user interface input devices may include, for example, medical imaging input devices such as computed tomography, magnetic resonance imaging, position emission tomography, medical ultrasonography devices. User interface input devices may also include, for example, audio input devices such as MIDI keyboards, digital musical instruments and the like.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 1000 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 1000 may comprise a storage subsystem 1018 that comprises software elements, shown as being currently located within a system memory 1010. System memory 1010 may store program instructions that are loadable and executable on processing unit 1004, as well as data generated during the execution of these programs.

Depending on the configuration and type of computer system 1000, system memory 1010 may be volatile (such as random access memory (RAM)) and/or non-volatile (such as read-only memory (ROM), flash memory, etc.) The RAM typically contains data and/or program modules that are immediately accessible to and/or presently being operated and executed by processing unit 1004. In some implementations, system memory 1010 may include multiple different types of memory, such as static random access memory (SRAM) or dynamic random access memory (DRAM). In some implementations, a basic input/output system (BIOS), containing the basic routines that help to transfer information between elements within computer system 1000, such as during start-up, may typically be stored in the ROM. By way of example, and not limitation, system memory 1010 also illustrates application programs 1012, which may include client applications, Web browsers, mid-tier applications, relational database management systems (RDBMS), etc., program data 1014, and an operating system 1016. By way of example, operating system 1016 may include various versions of Microsoft Windows®, Apple Macintosh®, and/or Linux operating systems, a variety of commercially-available UNIX® or UNIX-like operating systems (including without limitation the variety of GNU/Linux operating systems, the Google Chrome® OS, and the like) and/or mobile operating systems such as iOS, Windows® Phone, Android® OS, BlackBerry® 10 OS, and Palm® OS operating systems.

Storage subsystem 1018 may also provide a tangible computer-readable storage medium for storing the basic programming and data constructs that provide the functionality of some embodiments. Software (programs, code modules, instructions) that when executed by a processor provide the functionality described above may be stored in storage subsystem 1018. These software modules or instructions may be executed by processing unit 1004. Storage subsystem 1018 may also provide a repository for storing data used in accordance with some embodiments.

Storage subsystem 1000 may also include a computer-readable storage media reader 1020 that can further be connected to computer-readable storage media 1022. Together and, optionally, in combination with system memory 1010, computer-readable storage media 1022 may comprehensively represent remote, local, fixed, and/or removable storage devices plus storage media for temporarily and/or more permanently containing, storing, transmitting, and retrieving computer-readable information.

Computer-readable storage media 1022 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 1000.

By way of example, computer-readable storage media 1022 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD, and Blu-Ray® disk, or other optical media. Computer-readable storage media 1022 may include, but is not limited to, Zip® drives, flash memory cards, universal serial bus (USB) flash drives, secure digital (SD) cards, DVD disks, digital video tape, and the like. Computer-readable storage media 1022 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 1000.

Communications subsystem 1024 provides an interface to other computer systems and networks. Communications subsystem 1024 serves as an interface for receiving data from and transmitting data to other systems from computer system 1000. For example, communications subsystem 1024 may enable computer system 1000 to connect to one or more devices via the Internet. In some embodiments communications subsystem 1024 can include radio frequency (RF) transceiver components for accessing wireless voice and/or data networks (e.g., using cellular telephone technology, advanced data network technology, such as 3G, 4G or EDGE (enhanced data rates for global evolution), WiFi (IEEE 802.11 family standards, or other mobile communication technologies, or any combination thereof), global positioning system (GPS) receiver components, and/or other components. In some embodiments communications subsystem 1024 can provide wired network connectivity (e.g., Ethernet) in addition to or instead of a wireless interface.

In some embodiments, communications subsystem 1024 may also receive input communication in the form of structured and/or unstructured data feeds 1026, event streams 1028, event updates 1030, and the like on behalf of one or more users who may use computer system 1000.

By way of example, communications subsystem 1024 may be configured to receive data feeds 1026 in real-time from users of social networks and/or other communication services such as Twitter® feeds, Facebook® updates, web feeds such as Rich Site Summary (RSS) feeds, and/or real-time updates from one or more third party information sources.

Additionally, communications subsystem 1024 may also be configured to receive data in the form of continuous data streams, which may include event streams 1028 of real-time events and/or event updates 1030, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 1024 may also be configured to output the structured and/or unstructured data feeds 1026, event streams 1028, event updates 1030, and the like to one or more databases that may be in communication with one or more streaming data source computers coupled to computer system 1000.

Computer system 1000 can be one of various types, including a handheld portable device (e.g., an iPhone® cellular phone, an iPad® computing tablet, a PDA), a wearable device (e.g., a Google Glass® head mounted display), a PC, a workstation, a mainframe, a kiosk, a server rack, or any other data processing system.

Due to the ever-changing nature of computers and networks, the description of computer system 1000 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have beeen described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A system comprising:
a first processing chamber configured to perform a first fabrication process on a wafer;
a second processing chamber configured to perform a second fabrication process on the wafer;
a transfer chamber coupled to the first processing chamber and the second processing chamber, wherein the transfer chamber comprises a sensor configured to measure wafer bowing characteristics associated with a bow of the wafer after the first fabrication process is performed on the wafer and before the second fabrication process is performed on the wafer;
a controller configured to perform operations comprising:
determining recipe parameters to reduce the bow of the wafer based at least in part on the wafer bowing characteristics; and
controlling environmental conditions in the transfer chamber and/or causing the second processing chamber to perform the second fabrication process using the recipe parameters.

2. The system of claim 1, wherein the second processing chamber includes a pedestal, the pedestal including an electrostatic chuck and one or more heating zones.

3. The system of claim 2, wherein the pedestal includes pins; and
wherein causing the second processing chamber to perform the second fabrication process includes causing wafer to soak in the second processing chamber on the pins for a time length based at least in part on the recipe parameters.

4. The system of claim 3, wherein causing the second processing chamber to perform the second fabrication process includes causing the second processing chamber to heat to a temperature based at least in part on the recipe parameters.

5. The system of claim 2, wherein the one or more heating zones includes at least one inner zone and at least one outer zone;
wherein causing the second processing chamber to perform the second fabrication process includes causing the at least one inner heating zone and the at least one outer heating zone to heat to different temperatures to reduce the bow of the wafer, the different temperatures being based at least in part on the recipe parameters.

6. The system of claim 2, wherein causing the second processing chamber to perform the second fabrication process includes:
setting a chucking voltage of the electrostatic chuck based at least in part on the recipe parameters; and
adjusting the chucking voltage of the electrostatic chuck based at least in part on an indication of film thickness deposited by the second fabrication process in the second processing chamber.

7. The system of claim 1, wherein causing the second processing chamber to perform the second fabrication process includes setting a radio-frequency power applied to the second processing chamber based at least in part on the recipe parameters.

8. The system of claim 1, wherein determining recipe parameters for reducing the bow of the wafer is further based at least in part on throughput requirements for the system.

9. The system of claim 1, wherein determining the recipe parameters to reduce the bow of the wafer comprises adjusting a spacing between the wafer and the shower head in the first or second processing chamber to dynamically adjust a deposition rate or deposition uniformity.

10. A method to reduce the bow of a wafer, the method comprising:
receiving, from a sensor coupled to a transfer chamber, wafer bowing characteristics associated with a bow of the wafer, the wafer bowing characteristics measured by the sensor, the transfer chamber coupled to a first processing chamber and a second processing chamber, the first processing chamber configured to perform a first fabrication process on the wafer, the second processing chamber configured to perform a second fabrication process on the wafer;
determining recipe parameters for reducing the bow of the wafer based at least in part on the wafer bowing characteristics; and
causing the second processing chamber to perform the second fabrication process using the recipe parameters.

11. The method of claim 10, wherein the wafer bowing characteristics are measured by the sensor as the wafer moves through the transfer chamber between the first processing chamber configured to perform the first fabrication process and the second processing chamber configured to perform the second fabrication process.

12. The method of claim 10, wherein the wafer bowing characteristics include a type of bowing comprising convex, concave, and combination.

13. The method of claim 10, wherein the wafer bowing characteristics include displacement of one or more points of the wafer in comparison to a plane or the sensor.

14. The method of claim 13, wherein the one or more points are distributed along a line across a diameter of the wafer.

15. The method of claim 13, wherein the one or more points are distributed along two intersecting lines across the wafer.

16. The method of claim 13, wherein the one or more points are distributed along a circle at a radius from a center of the wafer.

17. The method of claim 13, wherein determining recipe parameters for reducing the bow of the wafer is further based at least in part on a thickness of film to be deposited by the second fabrication process in the second processing chamber.

18. One or more non-transitory computer-readable media comprising instructions that, when executed by one or more processors, cause the one or more processors to perform operations comprising:
receiving, from a sensor coupled to a transfer chamber, wafer bowing characteristics associated with a bow of the wafer, the wafer bowing characteristics measured by the sensor, the transfer chamber coupled to a first processing chamber and a second processing chamber, the first processing chamber configured to perform a first fabrication process on the wafer, the second processing chamber configured to perform a second fabrication process on the wafer;
determining recipe parameters for reducing the bow of the wafer based at least in part on the wafer bowing characteristics; and
controlling environmental conditions in the transfer chamber using the recipe parameters.

19. The one or more non-transitory computer-readable media of claim 18, wherein controlling environmental conditions in the transfer chamber includes causing the wafer to soak in the transfer chamber for a time length based at least in part on the recipe parameters.

20. The one or more non-transitory computer-readable media of claim 19, wherein controlling environmental conditions in the transfer chamber includes causing the transfer chamber to heat to a temperature based at least in part on the recipe parameters.
